(19) United States
(12) Patent Application Publication
(10) Pub. No.: US 2010/0195411 A1
(43) Pub. Date: Aug. 5, 2010

(54) SEMICONDUCTOR MEMORY DEVICE AND FAIL BIT DETECTION METHOD IN SEMICONDUCTOR MEMORY DEVICE

(76) Inventor: Naofumi ABIKO, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/694,605

(22) Filed: Jan. 27, 2010

(30) Foreign Application Priority Data
Jan. 30, 2009 (JP) 2009-019680

(51) Int. Cl. G11C 16/06; G11C 29/00; G11C 7/10

(52) U.S. Cl. 365/189.05; 365/200

(57) ABSTRACT

A memory cell array includes a plurality of pages. Each page of the plurality of pages is divided into a plurality of segments, and one segment is constituted of a plurality of bytes. A fail detection circuit receives signals of the plurality of fail bit detection signal lines, and the fail detection circuit collectively detects presence/absence of a fail bit in the memory cell array in units of segments.

### CROSS-REFERENCE TO RELATED APPLICATIONS

This application is based upon and claims the benefit of priority from prior Japanese Patent Application No. 2009-019680, filed Jan. 30, 2009, the entire contents of which are incorporated herein by reference.

### BACKGROUND OF THE INVENTION

1. Field of the Invention

The present invention relates to a semiconductor memory device such as a NAND flash memory or the like, and more particularly, to a circuit configured to carry out an operation of detecting a fail bit.

2. Description of the Related Art

With an increase in the use of handling data of a large quantity such as an image, animation or the like in a mobile device or the like, demand for NAND flash memory is increasing rapidly. Particularly, a multiple-valued NAND flash memory utilizing a multiple-value technique enabling one memory cell to store data of two bits or three bits makes it possible to store data of a larger quantity by using a small chip area. In a NAND flash memory, a data write operation or data read operation is carried out, with respect to a memory cell array, for each page, in which for example, 8 Kbytes are defined as one unit. With the miniaturization of the element, write characteristics of the memory cell has been deteriorated, and it has become very difficult to carry out control to narrow the threshold distribution. Furthermore, with an increase in the number of bits of data to be written to one memory cell, it is necessary to write data little by little with a narrower program voltage width, and hence the write time tends to become increasingly longer.

In Jpn. Pat. Appln. KOKAI Publication No. 2008-4178, a nonvolatile memory in which a page is divided into segments of a predetermined length, and fail detection is collectively carried out for each segment in an analog manner is disclosed.

### BRIEF SUMMARY OF THE INVENTION

According to a first aspect of the present invention, there is provided a semiconductor memory device comprising:

a memory cell array which includes a plurality of pages, in which one page is divided into a plurality of segments, and one segment is constituted of a plurality of bytes;

a plurality of fail bit signal output circuits in each of which a signal indicating whether or not a fail bit is present is generated in units of segments on the basis of data read from the memory cell array, and the generated signal is output to a plurality of fail bit detection signal lines; and

a fail detection circuit configured to receive signals of the plurality of fail bit detection signal lines, and collectively detect presence/absence of a fail bit in the memory cell array in units of segments.

According to a second aspect of the present invention, there is provided a fail bit detection method in a semiconductor memory device comprising a memory cell array which includes a plurality of pages, in which one page is divided into a plurality of segments, and one segment is constituted of a plurality of bytes comprising:

generating a signal indicating whether or not a fail bit is present in units of segments on the basis of data read from the memory cell array, and outputting the generated signal to a plurality of fail bit detection signal lines; and

collectively detecting presence/absence of a fail bit in the memory cell array in units of segments on the basis of signals of the plurality of fail bit detection signal lines.

### BRIEF DESCRIPTION OF THE SEVERAL VIEWS OF THE DRAWING

FIG. 1 is a block diagram schematically showing the overall configuration of a NAND flash memory according to a first embodiment of the present invention;

FIG. 2 is a block diagram showing a main part in FIG. 1 extracted as an example;

FIG. 3 is a block diagram showing the configuration of an extracted part of the circuit of FIG. 2;

FIG. 4 is a circuit diagram showing the configuration of a part of an FBUS detect circuit provided in each YCOM shown in FIG. 2;

FIG. 5 is a flowchart showing an example of a fail bit detection operation at the program time in the NAND flash memory of the first embodiment;

FIG. 6 is a flowchart showing an example of a segment bit scan operation in FIG. 5;

FIG. 7 is an explanatory view showing a method of searching for a YCOM in which a fail byte is present by using a dichotomizing search method;

FIG. 8 is a flowchart showing an example of the search method of FIG. 7;

FIG. 9 is a timing chart showing the example of a fail bit detection operation shown in FIG. 5;

FIG. 10 is a block diagram showing, as an example, an extracted main part of a NAND flash memory according to a second embodiment of the semiconductor memory device of the present invention;

FIG. 11 is a circuit diagram showing the configuration of a part of the circuit shown in FIG. 10;

FIG. 12 is a flowchart showing an example of a fail bit detection operation at the program time in the NAND flash memory of the second embodiment; and

FIG. 13 is a timing chart showing the example of a fail bit detection operation shown in FIG. 12.

### DETAILED DESCRIPTION OF THE INVENTION

The present invention will be described below by way of examples with reference to the drawings. In the description, common parts throughout all the drawings are denoted by common reference symbols to be described.

### First Embodiment

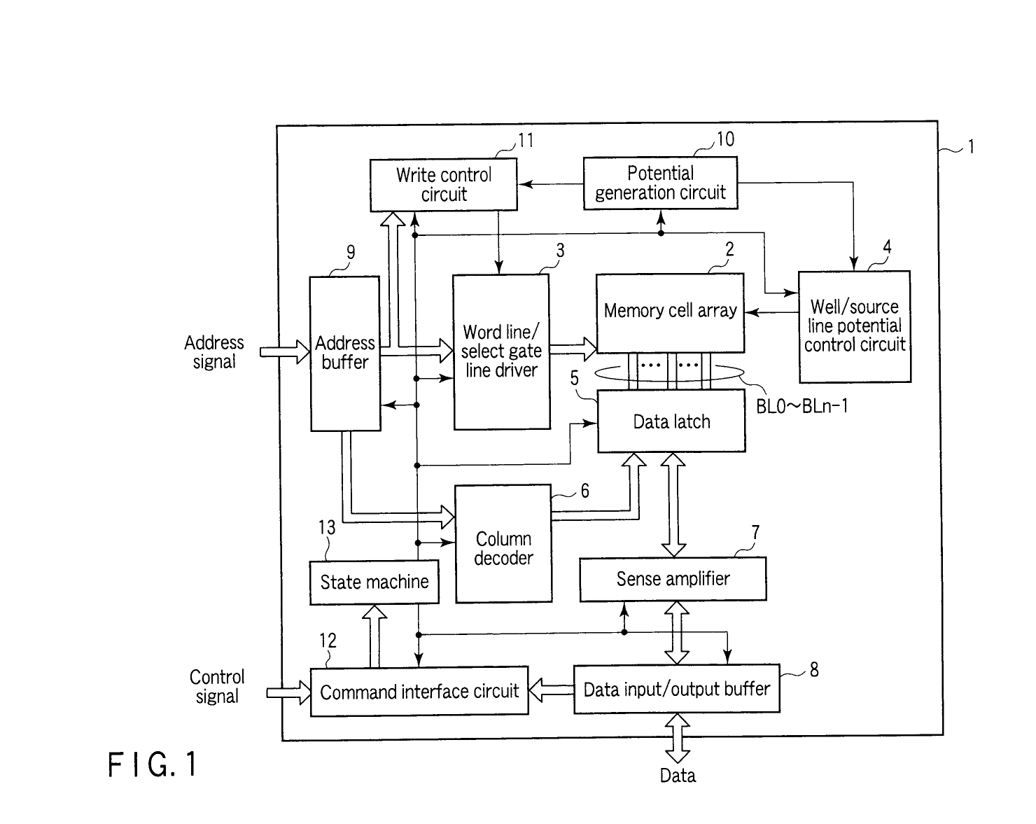

FIG. 1 is a block diagram schematically showing the overall configuration of a NAND flash memory according to a first embodiment of the present invention. A memory chip 1 of the NAND flash memory of this embodiment includes a memory cell array 2, word line/select gate line driver 3, well/source line potential control circuit 4, data latch 5, column decoder 6, sense amplifier 7, data input/output buffer 8, address buffer 9, potential generation circuit 10, write control circuit 11, command interface circuit 12, and state machine 13.

The memory cell array 2 includes a plurality of cell units. Each cell unit includes a series circuit in which a plurality of memory cells are connected in series, and two select gate transistors connected to one end and the other end of the series circuit. In the memory cell array 2, data read or data write is carried out in units of pages, and erase is enabled in units of blocks, the block being constituted of a plurality of pages. The word line/select gate line driver 3 is provided for each block of the memory cell array, includes a row decoder configured to select a row of the memory cell array 2 on the basis of a row address signal, and controls the potential of the word line or select gate line in the memory cell array 2 on the basis of the operation mode. The well/source line potential control circuit 4 controls the potential of the well region and potential of the source line in the memory cell array 2 on the basis of the operation mode.

The data latch 5 stores therein program data corresponding to one page at the program time, and stores therein read data corresponding to one page at the read time. The column decoder 6 selects a column of the memory cell array 2 on the basis of a column address signal. In this embodiment, a main column decoder, and a plurality of local sub-column decoder (hereinafter referred to as YCOMs) are provided. The main column decoder carries out selection of a YCOM, and selection of a byte in the YCOM on the basis of part of the column address signal, and the YCOM selects a column of the memory cell array 2 on the basis of part of the column address signal. The sense amplifier 7 sense-amplifies data read from the memory cell array 2.

The data input/output buffer 8 is an interface of data input/output, and address buffer 9 is an input buffer of a row/column address signal. The potential generation circuit 10 generates, for example, a write potential (V_{program}) and transfer potential (Vₚₐₛₛ) at the program time, and inputs the generated potentials to the write control circuit 11. The write control circuit 11 carries out control of changing the write condition.

The column decoder 6 includes a collective detection circuit. The collective detection circuit detects whether or not data has been correctly written to a memory cell of the memory cell array 2 selected at the program time.

The command interface circuit 12 determines whether or not data input to the data input/output buffer 8 is command data on the basis a control signal generated by a chip (for example, a host microcomputer) other than the memory chip 1 and, when the data is the command data, the circuit 12 transfers the command data to the state machine 13. The state machine 13 determines the operation mode of the flash memory on the basis of the command data, and controls the overall operations of the flash memory in accordance with the determined operation mode.

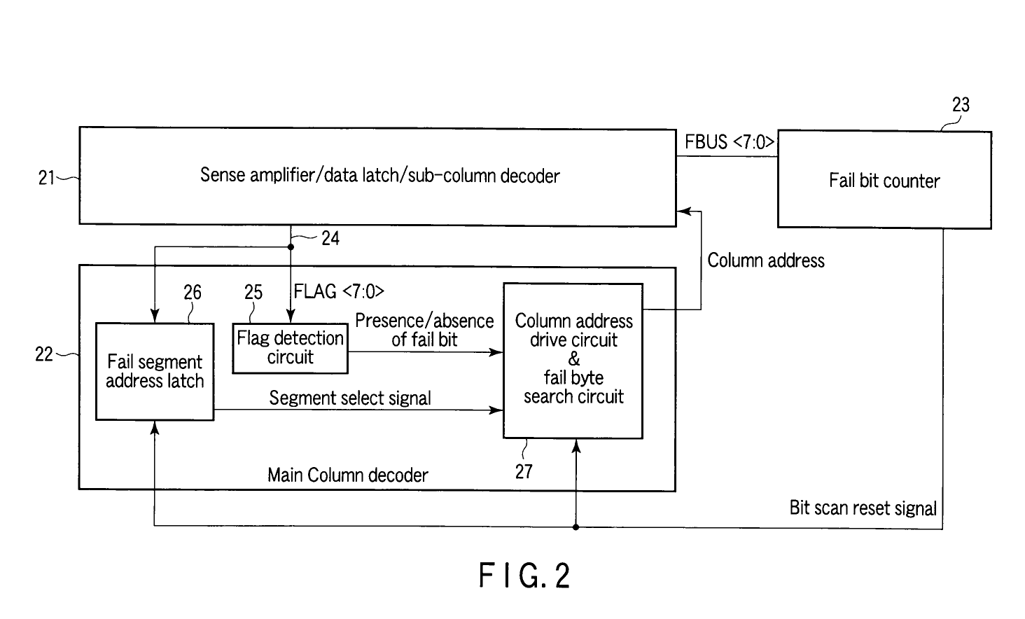

FIG. 2 is a block diagram showing a main part in FIG. 1 extracted as an example. Here, a sense amplifier/data latch/sub-column decoder (S/A data latch sub-column decoder) 21 is the collective expression of a data latch 5, sense amplifier 7, and a YCOM in the column decoder 6 which are shown in FIG. 1. Further, the main column decoder 22 indicates part of the column decoder 6 in FIG. 1, and further indicates a range including the collective detection circuit. A fail bit counter 23 is provided in a peripheral circuit of the memory cell array 2.

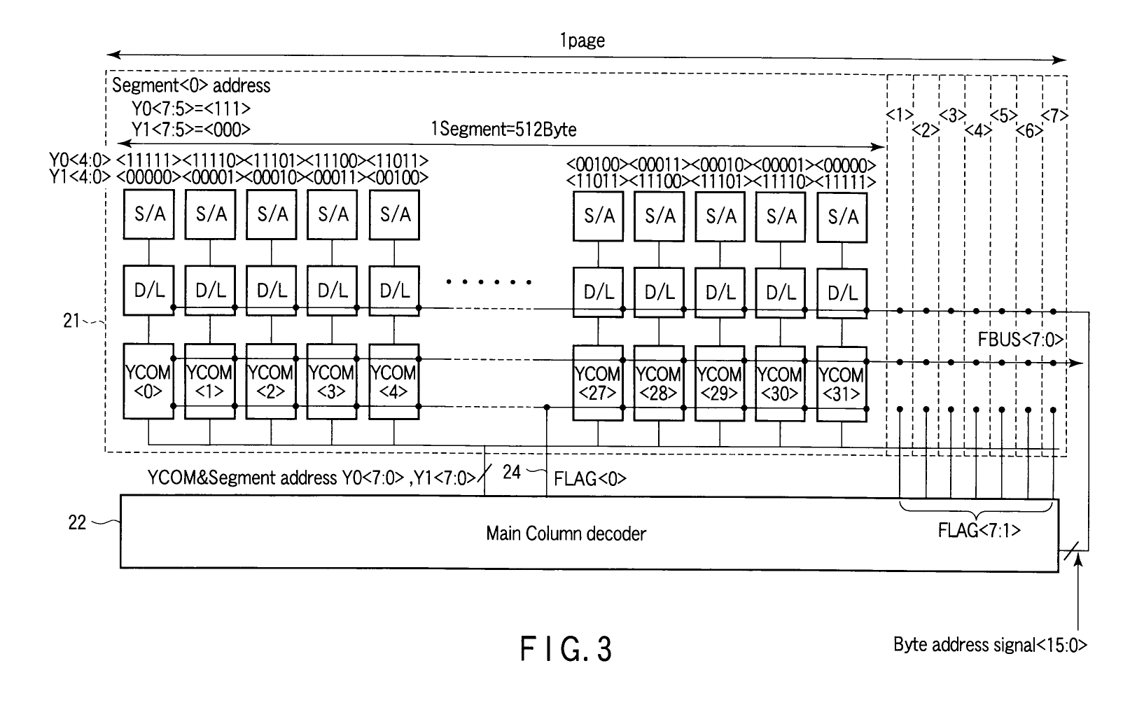

FIG. 3 is a block diagram showing the configuration of an extracted part of the circuit of FIG. 2. The NAND flash memory of this embodiment includes a plurality of pages, one page is divided into a plurality of segments, and one segment is constituted of a plurality of bytes. The memory cell array is divided into a plurality of pages in each of which one unit is constituted of, for example, 4 Kbytes, and each page is divided into 8 segments in each of which one unit is constituted of, for example, 512 Kbytes. Furthermore, each segment is constituted of 32 columns in each of which one unit is constituted of 16 bytes. Accordingly, one page is constituted of 256 columns. In order to access a column in one page, a column address signal of 12 bits is needed.

Regarding the column to be accessed, one of 8 segments of one page, and one of 32 columns in the selected segment are selected on the basis of complementary 8-bit signals YCOM & segment address signals; Y0 [symbol] 7:0 [symbol] and Y1 [symbol] 7:0 [symbol] of the 12-bit column address signal. It should be noted that [symbol] 7:0 [symbol] attached to the end of the signal Y0, Y1 or a signal to be described later means that each of the signals Y0 and Y1 is a signal of 8 bits constituted of [symbol] 0 [symbol] to [symbol] 7 [symbol] . In this case, one segment is selected by 3 bits of each of Y0 [symbol] 7:5 [symbol] and Y1 [symbol] 7:5 [symbol] out of Y0 [symbol] 7:0 [symbol] and Y1 [symbol] 7:0 [symbol] , and one column is selected by 4 bits of each of Y0 [symbol] 4:0 [symbol] and Y1 [symbol] 4:0 [symbol] . Further, a 16-bit byte address signal [symbol] 15:0 [symbol] obtained by decoding the remaining 4-bit address signal of the 12-bit column address signal is connected in common with all the columns, and 1 byte of 16 bytes in one column is selected by this signal.

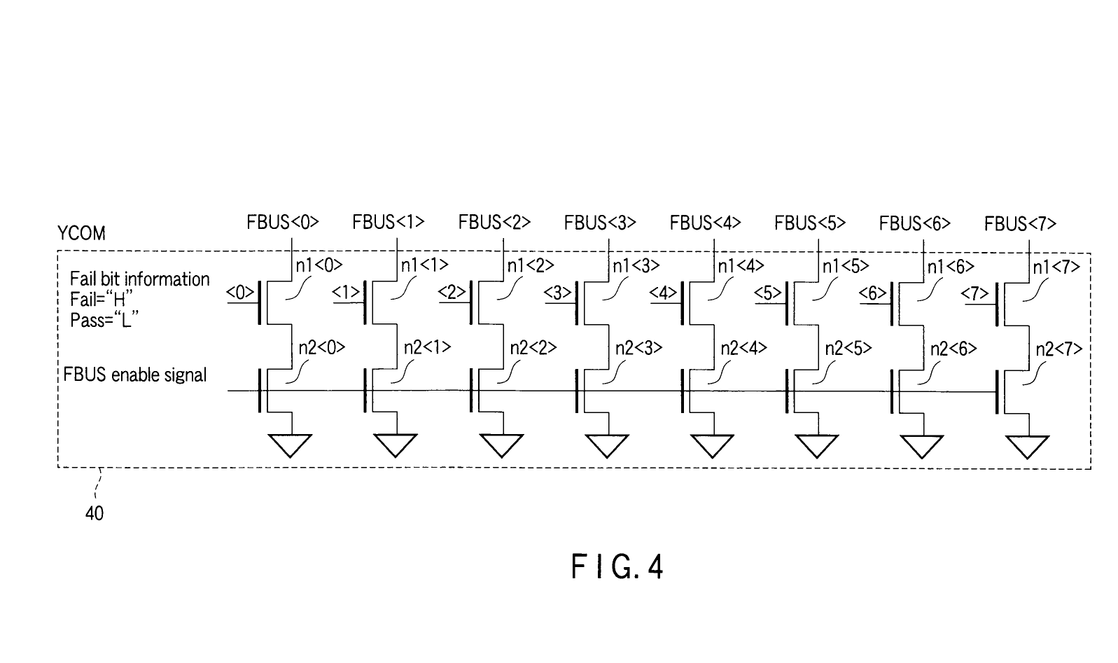

As a signal line used to transfer a result obtained by detecting which bit of the selected 1 byte is a fail bit, a total of 8 FBUS [symbol] 7:0 [symbol] are provided in such a manner that one FBUS corresponds to each bit in 1 byte. The FBUS [symbol] 7:0 [symbol] are wired in common with FBUS detect circuits (reference symbol 40 in FIG. 4 to be described later) provided in all the columns in the segment.

A fail bit counter 3 counts fail bit signals transferred from the FBUS [symbol] 7:0 [symbol] , and generates a bit scan reset signal used to reset a segment bit scan operation as will be described later.

Furthermore, in order to detect presence/absence of a fail bit in the 32 columns for each segment, one fail bit detection signal line 24 outputting a fail bit detection signal (flag signal) of 1 bit is wired for each segment. As described above, flag signals FLAG [symbol] 7:0 [symbol] of 8 bits taken out of the eight fail bit detection signal lines 24 in the whole page are input to the main column decoder 22.

The main column decoder 22 includes a circuit configured to collectively detect whether or not data have been correctly written to the memory cells of the page selected at the program time on the basis of the input of the 8-bit FLAG [symbol] 7:0 [symbol] , and specify in which segment a fail bit is present. That is, the main column decoder 22 includes, as shown in, for example, FIG. 2, a flag detection circuit 25 to which the FLAG [symbol] 7:0 [symbol] signals output from the sense amplifier data latch sub-column decoder 21 through the fail bit detection signal line 24 are input, fail segment address latch 26, and column address drive circuit & fail byte search circuit 27.

The flag detection circuit 25 processes the FLAG [symbol] 7:0 [symbol] input by using, for example, an OR circuit, collectively detects presence/absence of a fail bit in the whole one page, and outputs a collective detection result (signal indicating presence/absence of a fail bit). The fail segment address latch 26 stores therein a segment address at which a fail bit is present on the basis of the FLAG [symbol] 7:0 [symbol] input, and outputs a segment select signal.

The column address drive circuit & fail byte search circuit 27 selects only segments in which fail bits are detected on the basis of the fail bit presence/absence signal and segment select signal, and drives the column address to search for a fail byte in which a fail bit is present. As a result of this, it is possible to omit a fail bit detection operation of unconcerned segments. In this case, a bit scan reset signal is transferred from the fail bit counter 23 in order to reset the bit scan operation.

FIG. 4 is a circuit diagram showing the configuration of a part of an FBUS detect circuit 40 provided in each YCOM shown in FIG. 2. In this FBUS detect circuit 40, a plurality of first NMOS transistors n1 [symbol] 7:0 [symbol] , and second NMOS transistors n2 [symbol] 7:0 [symbol] are provided. The FBUS [symbol] 7:0 [symbol] are connected to drains of the first NMOS transistors n1 [symbol] 7:0 [symbol] , and fail bit information [symbol] 7:0 [symbol] (“H” for a failed bit, and “L” for a passed bit) is given to gates of the first NMOS transistors. Each of the second NMOS transistors n2 [symbol] 7:0 [symbol] is connected in series to corresponding one of the first NMOS transistors n1 [symbol] 7:0 [symbol] . An FBUS enable signal is input to a gate of each of the second NMOS transistors n2 [symbol] 7:0 [symbol] . The FBUS enable signal is rendered “H” only for a selected YCOM to turn on the second NMOS transistors n2 [symbol] 7:0 [symbol] , whereby the first NMOS transistors n1 [symbol] 7:0 [symbol] to which the fail bit information “H” is input are turned on, and the FBUS [symbol] 7:0 [symbol] connected to the first NMOS transistors n1 [symbol] 7:0 [symbol] are discharged.

Next, the operation at the program time and fail bit detection operation in the NAND flash memory of this embodiment will be roughly described below. In the program system of the NAND flash memory, a fail bit erroneously written to the memory cell array is subjected to error correction by using the ECC technique, whereby erroneous write of several bits is permitted. When the ECC technique is used, the number of error-correctable fail bits is a fixed value. Accordingly, it is necessary to count the number of fail bits which cannot be written at the program time. When the fail bit number is the allowable number or more, the program is carried out again, and when the fail bit number is less than the allowable number, the program is terminated, and error correction by the ECC can be carried out.

When the program operation is carried out, each time write is carried out at a certain program voltage, a verify operation is carried out to check the written state of the memory cell. At this time, when the write is completed, “1” is stored in the data latch circuit, and when the write is uncompleted, “0” is stored therein. Subsequently, a fail bit detection operation is carried out in order to determine whether or not the program has been completed.

As the fail bit detection operation, in general, a collective detection operation is carried out. In this collective detection operation, fail determination is collectively carried out for all the data latch circuits. At this time, even when only one fail bit is present, it is determined that the program is uncompleted, and the next program is started. Here, even when fail determination is output by the collective detection, if the fail bit number is within the allowable fail number that can be error-corrected by the ECC, it is determined that the program is completed. After the collective detection operation, the part in which a fail bit is present is checked, and a counting operation of counting the number of fail bits is carried out.

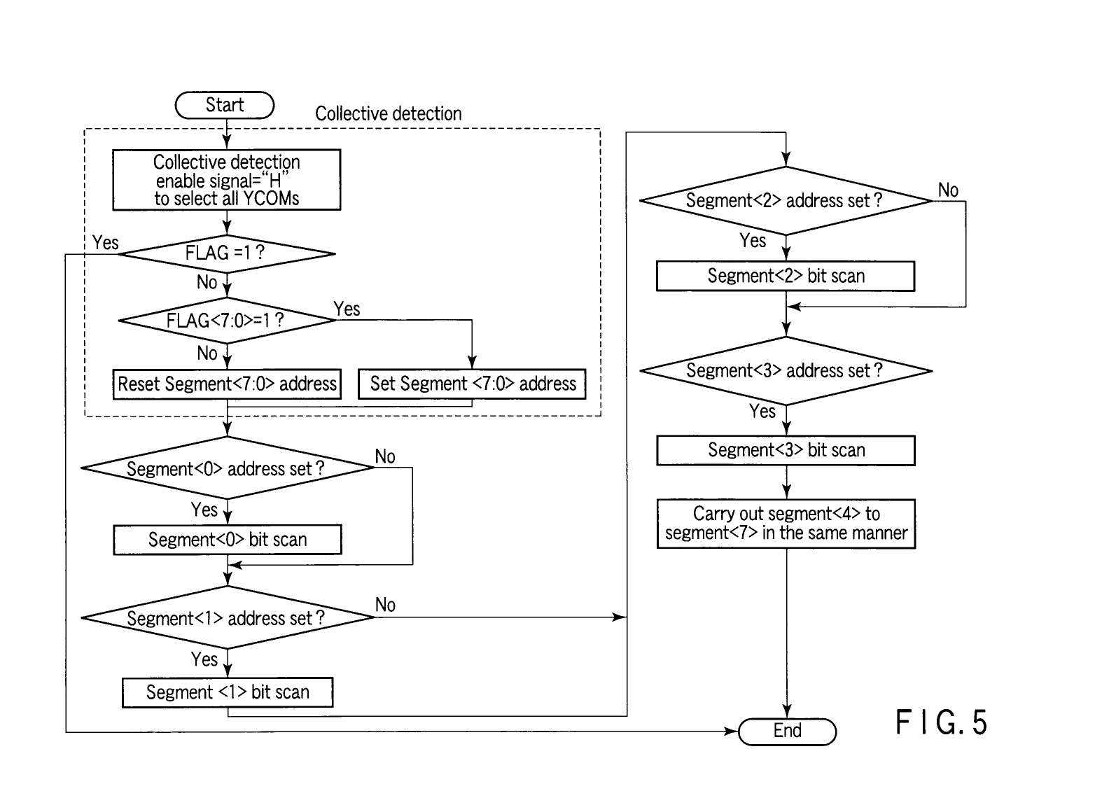

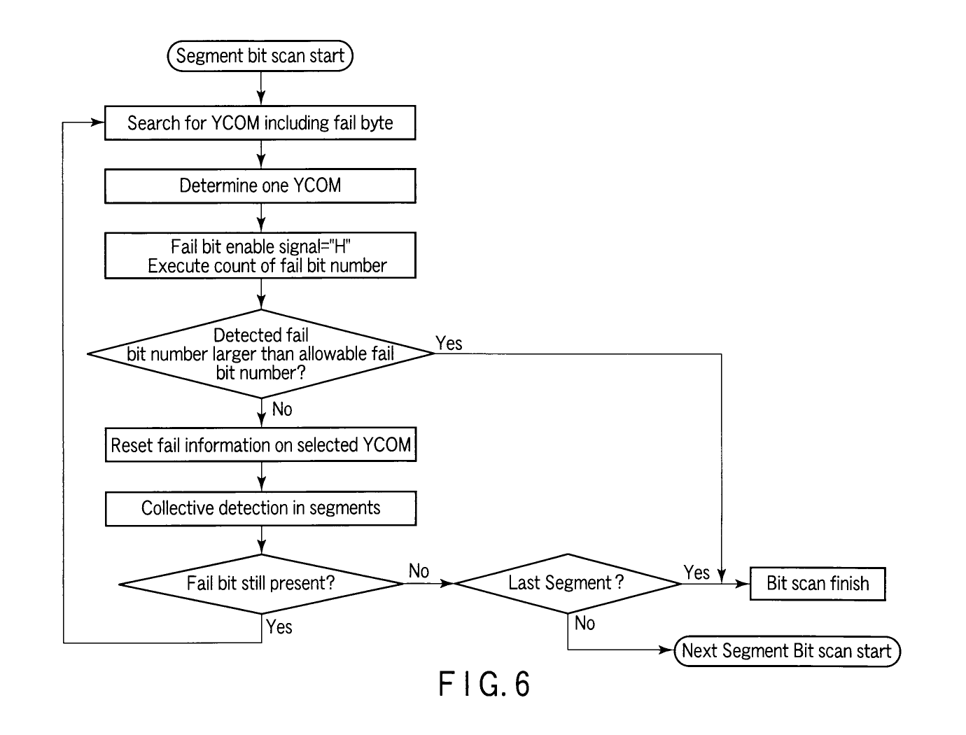

FIG. 5 is a flowchart showing an example of the fail bit detection operation at the program time in the NAND flash memory of the first embodiment, and FIG. 6 is a flowchart showing an example of the segment bit scan operation in FIG. 5.

As shown in FIG. 5, in the fail bit detection operation, first, a page collective detection operation is carried out. In this collective detection operation, all the columns are selected, a collective detection enable signal is rendered “H” (active level), and fail determination is collectively carried out for all the data items of the data latches 5. At this time, when no fail bit is detected, the program is completed (ended).

Conversely, even when it is determined that only one fail bit is present, it is determined that the program is uncompleted. As described above, even when it is determined by the collective detection that a fail bit is present, the number of fail bits is counted, and when the fail bit number is within the allowable number of fail bits that can be error-corrected by the ECC, it is determined that the program is completed.

In the above collective detection operation, as for the eight flag signals FLAG [symbol] 7:0 [symbol] , when a fail bit is present in the corresponding segment, “0” is output, and when no fail bit is present therein, “1” is output. In the main column decoder 22, the eight flag signals FLAG [symbol] 7:0 [symbol] are ORed with each other, and when at least one flag signal is of “0”, it is detected that an unwritten bit is present in the page. At the same time, the eight flag signals FLAG [symbol] 7:0 [symbol] are stored in the fail segment address latch 26 as an address of a segment in which a fail bit is present.

When the program has entered the phase of the segment fail bit detection operation while the program is in progress, data of the fail segment address latch 26 is read, a segment in which a fail bit is present is selected, and the segment bit scan operation is carried out. In this case, it is possible to determine in advance a segment to be bit-detected on the basis of data of the fail segment address latch 26, and hence it is possible to omit bit detection of an unconcerned segment. For example, in the case where only the FLAG [symbol] 0 [symbol] and FLAG [symbol] 2 [symbol] have output “0” as a result of the collective detection, when bit detection is carried out, it is determined that a YCOM corresponding to the addresses of Y0 [symbol] 7:5 [symbol] =111, and Y1 [symbol] 7:5 [symbol] =000, and YCOM corresponding to the addresses of Y0 [symbol] 7:5 [symbol] =101, and Y1 [symbol] 7:5 [symbol] =010 are the segments to be bit-detected. Accordingly, the search operation for a YCOM other than the above YCOMs is made unnecessary, and the bit detection time is shortened.

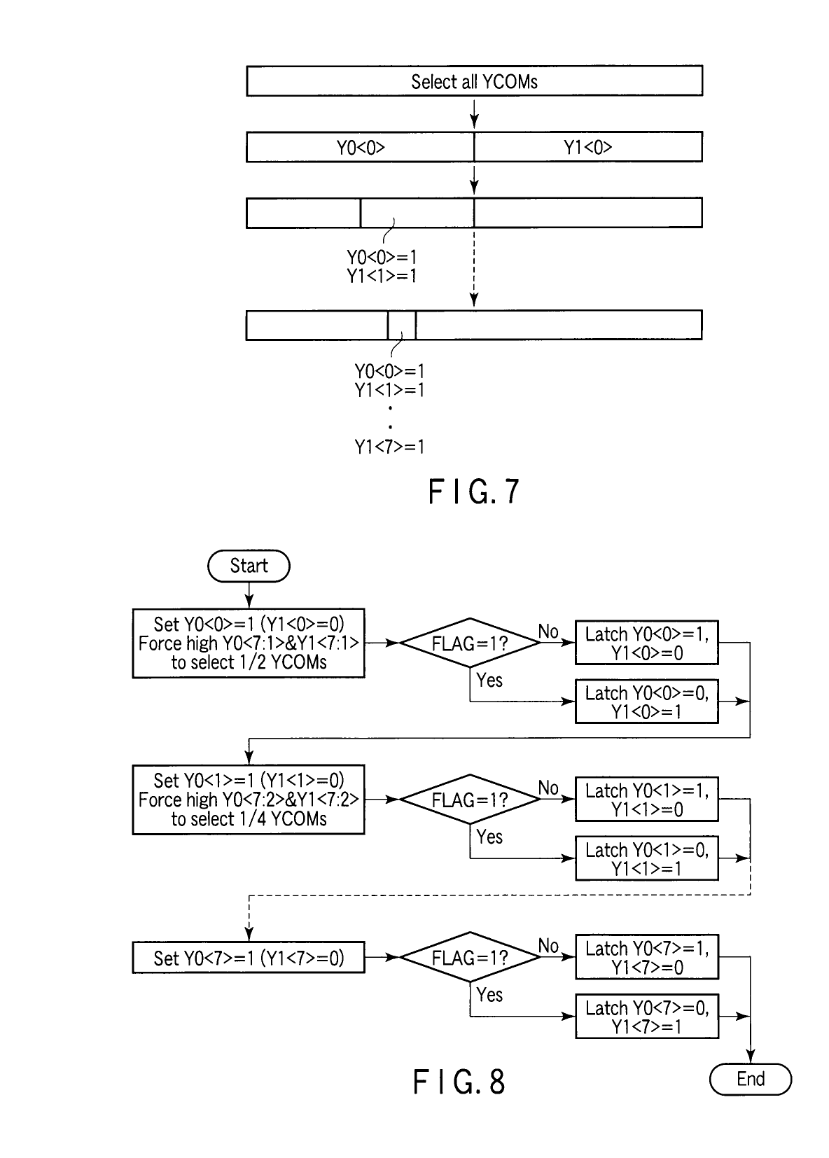

In the segment bit scan operation, as in the flowchart shown in, for example, FIG. 6, it is checked in which byte in which column of the segment, a fail bit is present (part in which a fail bit is present), and an operation of detecting the number of fail bits is carried out. First, as in the flowcharts shown in, for example, FIGS. 7 and 8, a column in which a fail byte is present is searched for by using the dichotomizing search method, and one column is determined to be selected. Then, the fail bit enable signal is rendered “H” (active level), and a result obtained by detecting which bit of the fail byte (8 bits) in the column is the fail bit is output to the FBUS [symbol] 7:0 [symbol] . The detection output to the FBUS [symbol] 7:0 [symbol] is input to the fail bit counter 23, and the number of fail bits is counted. When the counted result of the fail bit number is larger than the allowable fail bit number, the segment bit scan operation is finished, and the program operation is carried out again. When the counted result of the fail bit number is smaller than the allowable fail bit number, the fail bit information on the selected column is reset. Then, collective detection of checking whether or not a fail bit is still present in the segment in which the search is currently carried out is carried out. When a fail bit is still present therein as a result of the collective detection, the flow is returned to the process of column search again. Such operations are repeated, and when no fail bit is detected in the segment, the segment bit scan operation is terminated. Further, when a segment of the search object still remains, a segment bit scan operation for the next segment is started.

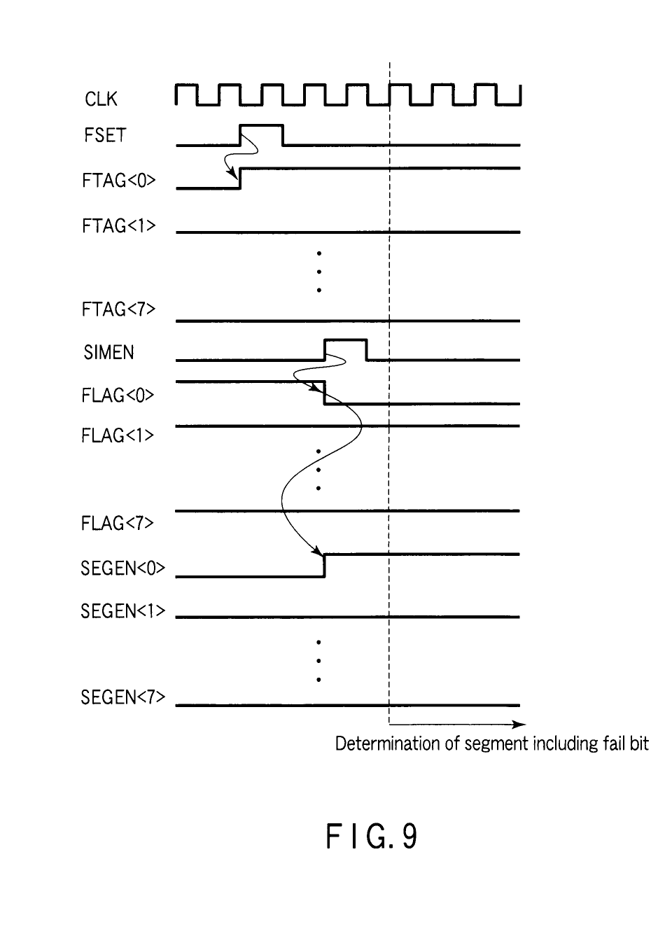

FIG. 9 is a timing chart showing the example of a fail bit detection operation shown in FIG. 5. The fail bit detection operation is carried out in synchronization with a clock signal CLK. First, fail bit information is set in the YCOM on the basis of an FSET signal. At this time, each of the fail bit data signals FTAG [symbol] 7:0 [symbol] becomes the “H” (active level) level when a fail bit is present. After this, the collective detection enable signal SIMEN becomes the “H” (active level) level, and the fail bit is transferred to the FLAG [symbol] 7:0 [symbol] . As a result of this, segment selection signals SEGEN [symbol] 7:0 [symbol] are set, and the segment of the search object is determined.

In this embodiment, assuming a case where a fail bit is present only in the segment [symbol] 0 [symbol] , the FTAG [symbol] 0 [symbol] becomes the “H” (active level) level on the basis of the FSET signal, the fail bit is transferred to the FLAG [symbol] 0 [symbol] on the basis of the SIMEN signal, and the FLAG [symbol] 0 [symbol] is discharged to become the “L” (active level). The FLAG [symbol] 7:0 [symbol] are held in the fail segment address latch 26 in the main column decoder 22, only the signal SEGEN [symbol] 0 [symbol] of the SEGEN [symbol] 7:0 [symbol] becomes the “H” (active level) level, and only the segment [symbol] 0 [symbol] in which the fail bit is present is selected.

As described above, according to the NAND flash memory of this embodiment, it is possible to incorporate an operation of searching for a segment (divided page) in which a fail bit is present into a fail bit detection operation of collectively detecting presence/absence of a fail bit for one page. Accordingly, it is possible to efficiently detect a segment in which a fail bit is present by one fail bit detection operation to specify the fail bit at a high speed, omit a fail bit detection operation for a divided page in which no fail bit is present, and shorten a fail bit detection time for one page. In this case, a part in which a fail bit is present is digitally searched for, and hence there is no possibility of false detection.

Further, in one page, the fail bit detection signal line is divided into eight lines to correspond to the eight segments, and hence an advantage that the load quantity of each fail bit detection signal line becomes smaller, and the transfer speed of the detection signal is improved is obtained.

It should be noted that in the above embodiment, although the YCOM plays a role as a sub-column decoder corresponding to 16 bytes, various patters in which the YCOM corresponds to 8 bytes, 32 bytes, and the like are conceivable. By virtue of the presence of the YCOM, a large number of sense amplifiers share the data-input/output path, address selection, and detection circuit with each other, whereby speedup is enabled, reduction in the number of elements is enabled, and the circuit size is made smaller as a whole, this being effective for the future NAND flash memory.

### Second Embodiment

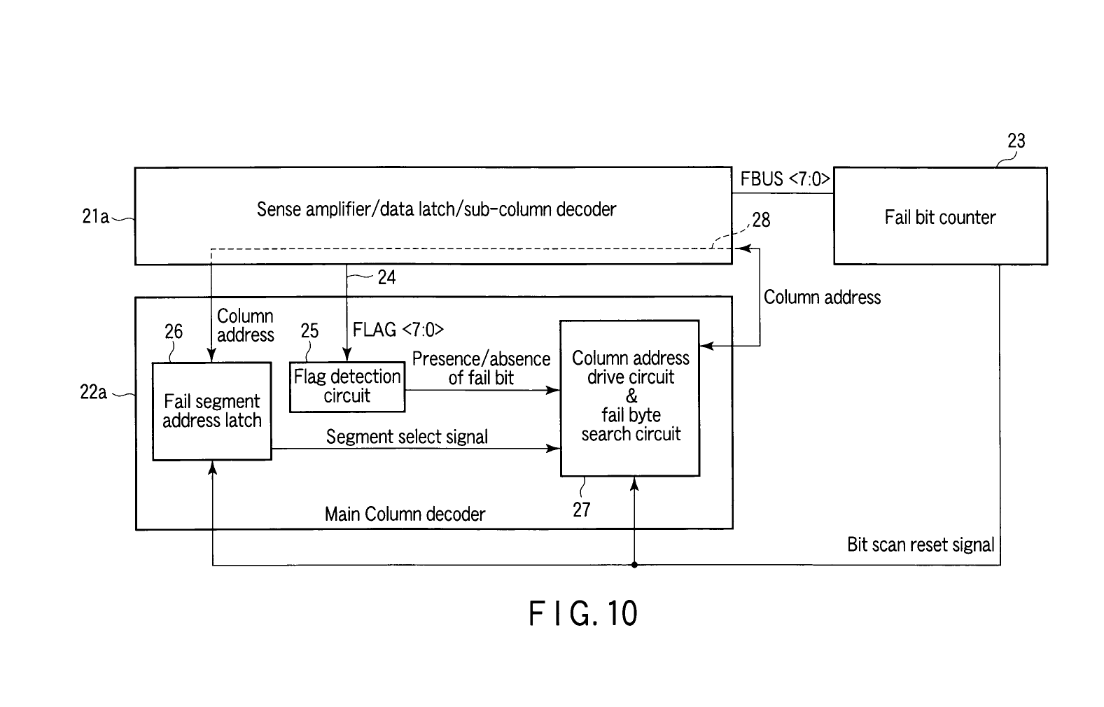

FIG. 10 is a block diagram of a NAND flash memory according to a second embodiment of the semiconductor memory device of the present invention, in which the main part in FIG. 1 is extracted and shown as an example in the same manner as in FIG. 2. In the second embodiment, as compared with the first embodiment described previously with reference to FIG. 2, the configuration is changed from that in FIG. 2 in such a manner that a sub-column address signal line 28 of a sense amplifier data latch sub-column decoder 21a is used bidirectionally, and a column address signal driven by a sub-column decoder is input to a fail segment address latch 26 of a main column decoder 22a. That is, the sub-column address signal line 28 is also used as the fail bit detection signal line 24.

When one page of the NAND flash memory of this embodiment is 4 Kbytes, a YCOM selection address is specified by 8-bit complementary signals of Y0 [symbol] 7:0 [symbol] and Y1 [symbol] 7:0 [symbol] , and there are 16 decode signals used for YCOM selection. By connecting 16 YCOMs to one signal, it is possible to divide 256 YCOMs into 16 segments.

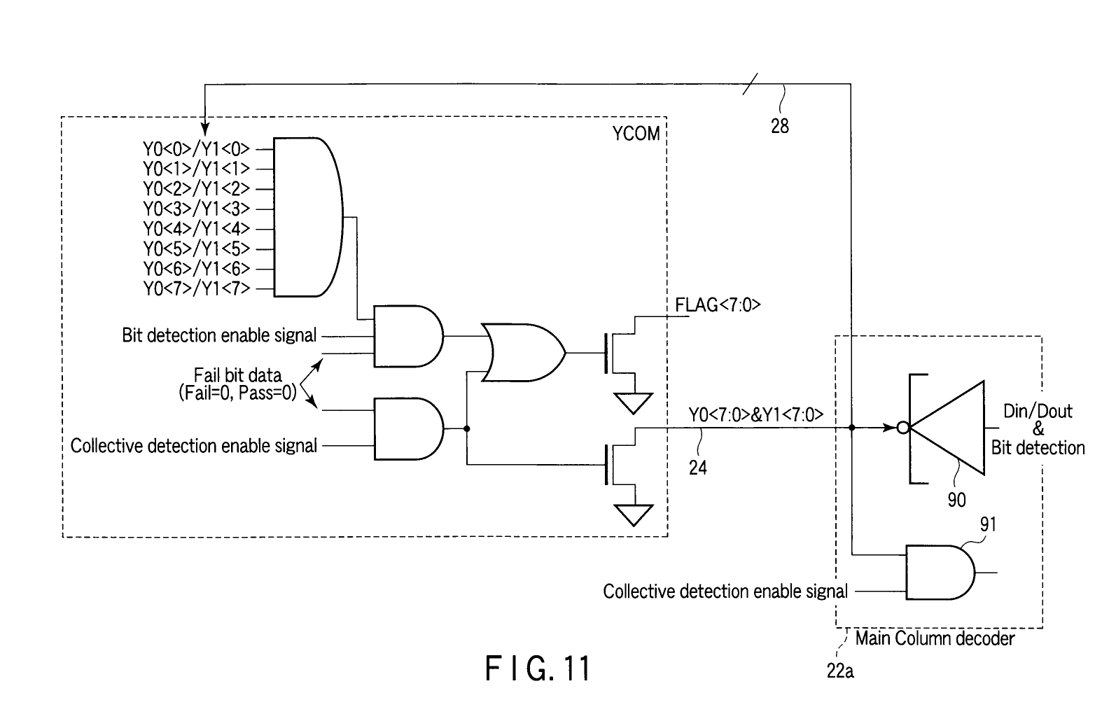

FIG. 11 is a circuit diagram showing an extracted part in which the sub-column address signal line (YCOM selection signal line) 28 driven by the main column decoder 22a shown in FIG. 10 is also used as the fail bit detection signal line 24 in the sense amplifier data latch sub-column decoder 21a. As the YCOM selection drive circuit 90 in the main column decoder 22a, for example, a tri-state buffer circuit is used. At the YCOM selection time, the YCOM selection drive circuit 90 is controlled to be in the enable state, and outputs a YCOM selection signal to the YCOM selection signal line 28, and at the collective detection operation time, the circuit 90 is controlled to be in the disable state.

Conversely, the fail bit detection circuit of the YCOM is controlled, at the collective detection operation time, to be in the enable state, and outputs FBUS signals Y0 [symbol] 7:0 [symbol] or Y1 [symbol] 7:0 [symbol] from the fail bit detection signal output stage (for example, an NMOS transistor) to the fail bit detection signal line 24 in accordance with presence/absence of the fail bit. Further, an input stage circuit 91 of the fail segment address latch 26 in the main column decoder 22a is controlled, at the collective detection operation time, to be in the enable state, acquires the FLAG Y0 [symbol] 7:0 [symbol] and Y1 [symbol] 7:0 [symbol] of the fail bit detection signal line 24, and causes the fail segment address latch 26 to latch the acquired flags as a segment selection address. It should be noted that the fail bit detection circuit of the YCOM is controlled to be in the enable state by the collective detection enable signal or bit detection enable signal, and outputs a fail bit detection signal from the FLAG signal output stage (for example, an NMOS transistor) to the FLAG [symbol] 7:0 [symbol] .

By the operations described above, it is possible to carry out the collective detection operation and, at the same time, carry out an operation (segment collective detection) of specifying a segment in which a fail bit is present in units of about 256 bytes. Accordingly, at the actual fail bit detection time, it becomes unnecessary to search a YCOM in which no fail bit is present for a fail bit. Further, an existing column address signal line is used, and hence it is unnecessary to newly provide a signal line.

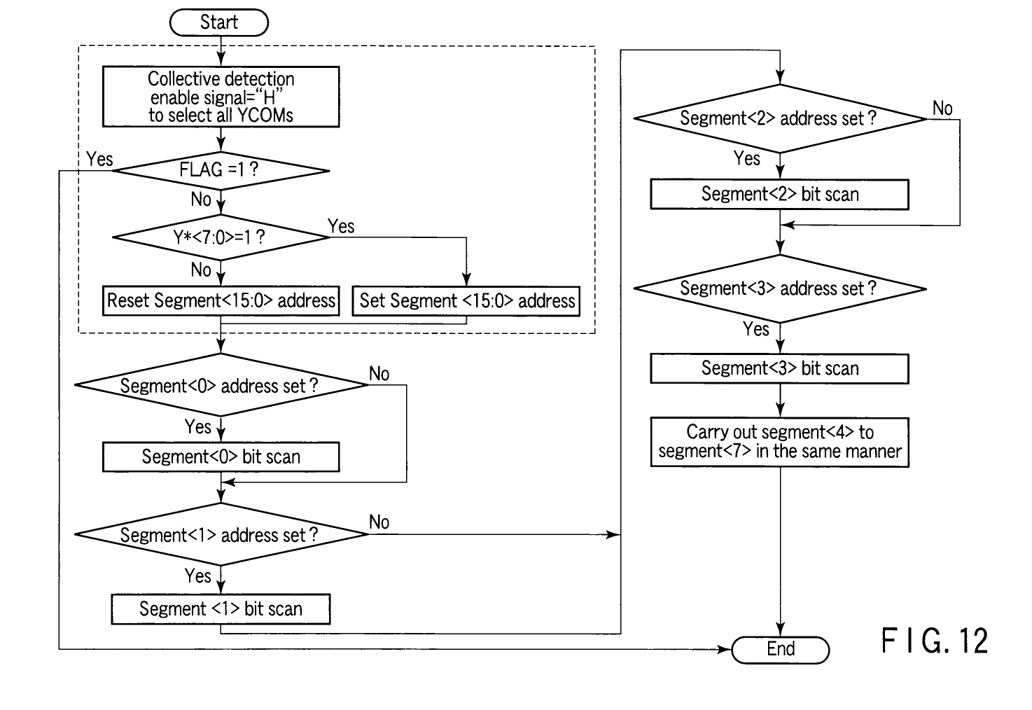

FIG. 12 is a flowchart showing an example of a fail bit detection operation at the program time in the NAND flash memory of this embodiment. This flowchart differs from the flowchart shown in FIG. 5 in the first embodiment in the point that the fail bit detection operation is carried out for 16 segments.

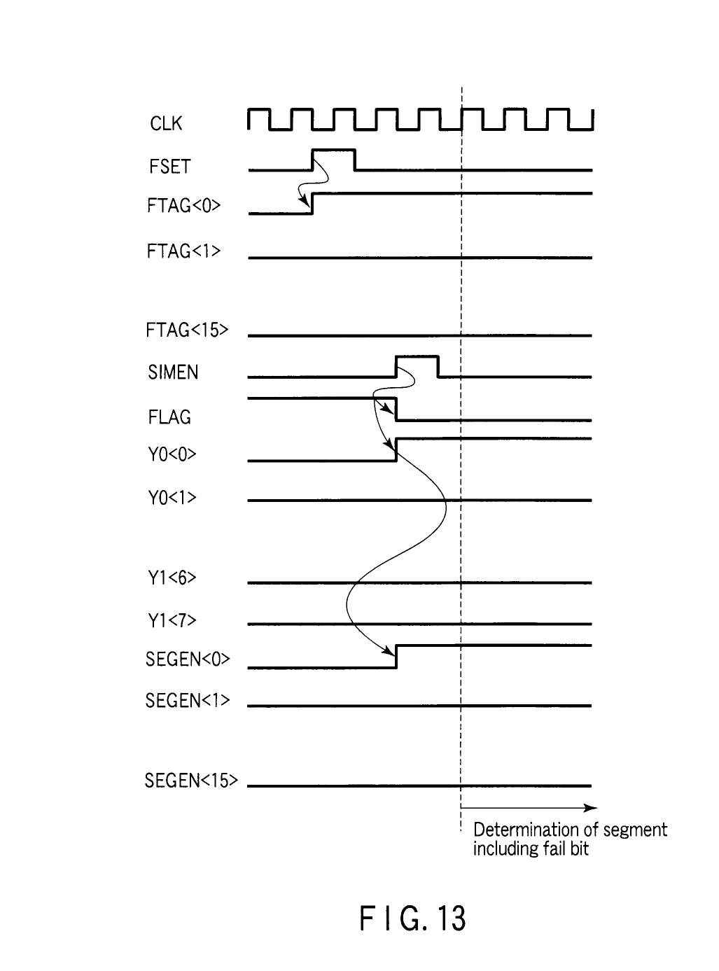

FIG. 13 is a timing chart showing the example of a fail bit detection operation shown in FIG. 12. This timing chart differs from the timing chart shown in FIG. 9 in the first example in the point that YCOM selection address signal Y0 [symbol] 7:0 [symbol] or Y1 [symbol] 7:0 [symbol] is used as a detection signal for a segment in which a fail bit is present.

According to the second embodiment, it is possible to specify a segment in which a fail bit is present in detail simultaneously with the collective detection operation, the number of signal lines is not increased, and the second embodiment is effective for the layout area.

With the coming of the NAND flash memory generation, the page length has become longer, a larger number of page division is required, and a larger number of address signal lines of the column decoder configured to division-specify the page become necessary. Accordingly, by using the existing column address signal line also as a line used to specify a segment in which a fail bit is present, it becomes unnecessary to additionally increase the number of signal lines.

It should be noted that in each of the above embodiments, a description has been given by taking the NAND flash memory as an example. However, the present invention can also be applied to a nonvolatile semiconductor memory such as a NOR flash memory or the like, and can appropriately be modified and implemented within the scope not deviating from the gist of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a memory cell array which includes a plurality of pages, in which one page is divided into a plurality of segments, and one segment is constituted of a plurality of bytes;
a plurality of fail bit signal output circuits in each of which a signal indicating whether or not a fail bit is present is generated in units of segments on the basis of data read from the memory cell array, and the generated signal is output to a plurality of fail bit detection signal lines; and
a fail detection circuit configured to receive signals of the plurality of fail bit detection signal lines, and collectively detect presence/absence of a fail bit in the memory cell array in units of segments.

2. The device according to claim 1, wherein the fail detection circuit collectively detects presence/absence of a fail bit in the whole page on the basis of a logical OR signal of signals of the plurality of fail bit detection signal lines.

3. The device according to claim 1, further comprising a memory circuit configured to receive signals of the plurality of fail bit detection signal lines, and store therein an address corresponding to a segment in which a fail bit is present.

4. The device according to claim 3, further comprising a fail byte search circuit configured to carry out control to receive an output of the fail bit memory circuit, select only a segment in which a fail bit is present, and search for a fail bit position in a byte in which a fail bit is present.

5. The device according to claim 1, wherein each of the plurality of fail bit signal output circuits includes a plurality of data latches configured to latch data read from the memory cell array, and sub-column data configured to receive a plurality of data items latched by the plurality of data latches.

6. The device according to claim 1, wherein the memory cell array includes a plurality of NAND cell units.

7. The device according to claim 1, wherein a plurality of address signal lines configured to select a column in the segment are used as the plurality of fail bit detection signal lines.

8. A fail bit detection method in a semiconductor memory device comprising a memory cell array which includes a plurality of pages, in which one page is divided into a plurality of segments, and one segment is constituted of a plurality of bytes comprising:
generating a signal indicating whether or not a fail bit is present in units of segments on the basis of data read from the memory cell array, and outputting the generated signal to a plurality of fail bit detection signal lines; and
collectively detecting presence/absence of a fail bit in the memory cell array in units of segments on the basis of signals of the plurality of fail bit detection signal lines.

9. The method according to claim 8, wherein presence/absence of a fail bit in the whole page is collectively detected by ORing signals of the plurality of fail bit detection signal lines with each other.

10. The method according to claim 8, further comprising receiving signals of the plurality of fail bit detection signal lines, and storing an address corresponding to a segment in which a fail bit is present.

11. The method according to claim 10, further comprising selecting only a segment in which a fail bit is present on the basis of the address corresponding to the segment in which the fail bit is present, and searching for a fail bit position in a byte in which the fail bit is present.

12. The method according to claim 10, wherein a plurality of address signal lines configured to select a column in the segment are used as the plurality of fail bit detection signal lines.
